(19) United States
(12) Patent Application Publication
(10) Pub. No.: US 2026/0123012 A1
(43) Pub. Date: Apr. 30, 2026

(54) SEMICONDUCTOR DEVICE

(71) Applicants: KABUSHIKI KAISHA TOSHIBA, Kawasaki-shi (JP); TOSHIBA ELECTRONIC DEVICES & STORAGE CORPORATION, Kawasaki-shi (JP)

(72) Inventors: Kazuyuki ITO, Fujisawa (JP); Nobuhide YAMADA, Yokohama (JP); Takuo KIKUCHI, Kamakura (JP); Akira YOSHIOKA, Yokohama (JP); Takao NODA, Saitama (JP); Toru SUGIYAMA, Musashino (JP)

(73) Assignees: KABUSHIKI KAISHA TOSHIBA, Kawasaki-shi (JP); TOSHIBA ELECTRONIC DEVICES & STORAGE CORPORATION, Kawasaki-shi (JP)

(21) Appl. No.: 19/329,758

(22) Filed: Sep. 16, 2025

(30) Foreign Application Priority Data
Oct. 30, 2024 (JP) 2024-190912

(51) Int. Cl. H10D 64/27; H10D 30/47; H10D 64/00; H10D 64/68

(52) U.S. Cl. CPC H10D 64/518; H10D 30/475; H10D 64/112; H10D 64/68

(57) ABSTRACT

According to one embodiment, a semiconductor device includes a compound semiconductor layer located on a substrate; a first insulating film located on the compound semiconductor layer; a first gate electrode located on the first insulating film; a second gate electrode located above the first gate electrode; a second insulating film located between the first gate electrode and the second gate electrode; and a third insulating film arranged around the first gate electrode, the second gate electrode, and the second insulating film, the third insulating film having a higher relative dielectric constant than the first and second insulating films.

### CROSS-REFERENCE TO RELATED APPLICATIONS

This application is based upon and claims the benefit of priority from Japanese Patent Application No. 2024-190912, filed on Oct. 30, 2024; the entire contents of which are incorporated herein by reference.

### FIELD

Embodiments described herein relate generally to a semiconductor device.

### BACKGROUND

Electronic devices that include nitride semiconductors are utilized in switching devices such as high-speed electronic devices, power devices, etc.

It is desirable for a switching device to have a high breakdown voltage and a low on-resistance. Although a trade-off relationship determined by the element material exists between the breakdown voltage and the on-resistance, the use of a wide bandgap semiconductor such as a nitride semiconductor, silicon carbide (SIC), or the like as the element material can make the material-determined trade-off relationship better than that of silicon, thereby enabling a higher breakdown voltage and a lower on-resistance. An element that includes a nitride semiconductor such as GaN, AlGaN, or the like has excellent material characteristics and can realize a high performance switching device.

### BRIEF DESCRIPTION OF THE DRAWINGS

FIGS. 1A and 1B are cross-sectional views of a semiconductor device according to a first embodiment;

FIG. 2 is a schematic cross-sectional view showing effects of the semiconductor device;

FIGS. 3A to 3D are cross-sectional views showing a method for manufacturing the semiconductor device;

FIGS. 4A to 4D are cross-sectional views showing the method for manufacturing the semiconductor device;

FIGS. 5A to 5C are cross-sectional views of modifications of the semiconductor device according to the first embodiment;

FIGS. 6A and 6B are cross-sectional views of a semiconductor device according to a second embodiment; and

FIGS. 7A to 7C are cross-sectional views of modifications of the semiconductor device according to the second embodiment.

### DETAILED DESCRIPTION

According to one embodiment, a semiconductor device includes a compound semiconductor layer located on a substrate; a first insulating film located on the compound semiconductor layer; a first gate electrode located on the first insulating film; a second gate electrode located above the first gate electrode; a second insulating film located between the first gate electrode and the second gate electrode; and a third insulating film arranged around the first gate electrode, the second gate electrode, and the second insulating film, the third insulating film having a higher relative dielectric constant than the first and second insulating films.

Embodiments will now be described with reference to the drawings. The drawings are schematic or conceptual; and the dimensions, proportions, etc. of each drawing are not necessarily the same as the actual values thereof. Some embodiments described below illustrate devices and methods for embodying the technical ideas of the invention, and the technical ideas of the invention are not specified by the shapes, structures, arrangements, etc. of the components. In the following description, components having the same function and configuration are marked with like reference numerals, and a detailed description will be given only when necessary. In the present disclosure, the term “stacked” includes not only a case where layers are stacked in contact with each other, but also a case where the layers are stacked with another layer inserted therebetween.

### 1. First Embodiment

### 1.1 Semiconductor Device 1

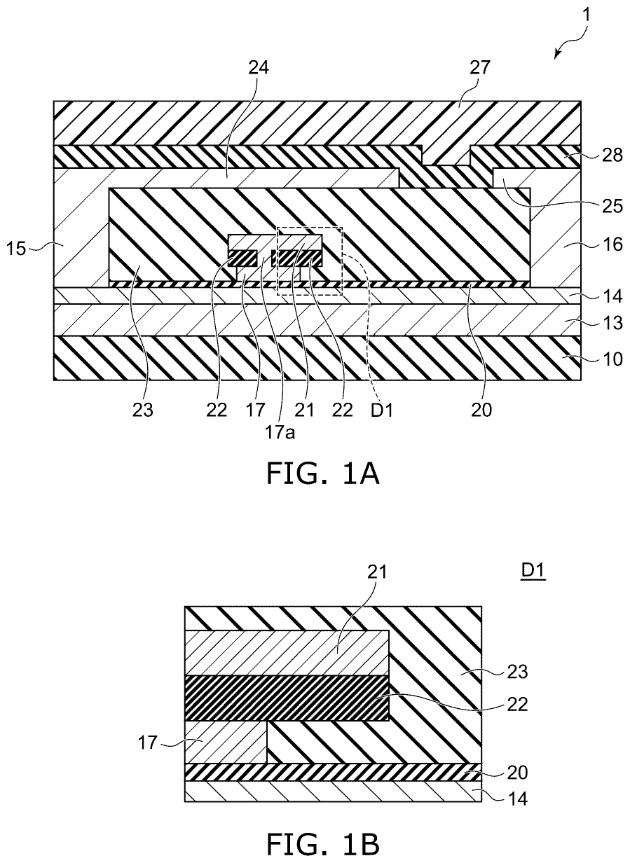

FIG. 1A is a cross-sectional view of a semiconductor device 1 according to an embodiment. FIG. 1B is an enlarged cross-sectional view of portion D1 of FIG. 1A. The semiconductor device 1 according to the embodiment includes a heterojunction FET (HFET: Heterojunction Field Effect Transistor) or a high electron mobility transistor (HEMT). The semiconductor device 1 includes a channel layer 13, a barrier layer 14, and various electrodes stacked in this order on a substrate 10.

The substrate 10 includes, for example, a silicon (Si) substrate having the (111) plane as a major surface. Sapphire (Al₂O₃), silicon carbide (SIC), gallium phosphide (GaP), indium phosphide (InP), gallium arsenide (GaAs), etc., may be used as the substrate 10. Also, a substrate that includes an insulating layer can be used as the substrate 10. For example, an SOI (Silicon On Insulator) substrate can be used as the substrate 10. It is sufficient for the substrate 10 to be a single-crystal substrate on which an epitaxial layer can be grown, and the substrate 10 is not limited to the examples described above.

The channel layer 13 is a layer in which a channel (a current path) of the transistor is formed. The channel layer 13 includes In_{X}Al_{Y}Ga_{(1-X-Y)}N (0≤X<1, 0≤Y<1, and 0≤X+Y<1). It is desirable for the channel layer 13 to be a nitride semiconductor layer having good crystallinity (high quality). According to the embodiment, the channel layer 13 includes GaN.

The barrier layer 14 forms a heterojunction with the channel layer 13. The barrier layer 14 includes a nitride semiconductor layer having a larger bandgap than the channel layer 13. The barrier layer 14 includes In_{X}Al_{Y}Ga_{(1-X-Y)}N (0≤X<1, 0≤Y<1, and 0≤X+Y<1). According to the embodiment, the barrier layer 14 includes undoped AlGaN. “Undoped” means that an impurity is not doped intentionally; for example, “undoped” includes an impurity amount that is incorporated in manufacturing processes, etc.

Strain is generated in the barrier layer 14 in the heterojunction structure of the channel layer 13 and the barrier layer 14 because the barrier layer 14 has a smaller lattice constant than the channel layer 13. The piezoelectric effect that is caused by the strain generates piezoelectric polarization inside the barrier layer 14, which generates a two-dimensional electron gas (2DEG) at the vicinity of the interface between the channel layer 13 and the barrier layer 14. The two-dimensional electron gas becomes a channel between a source electrode 15 and a drain electrode 16.

The source electrode 15 and the drain electrode 16 are separated from each other on the barrier layer 14. The source electrode 15 and the 2DEG have an ohmic contact via the barrier layer 14. Similarly, the drain electrode 16 and the 2DEG have an ohmic contact via the barrier layer 14. In other words, the source electrode 15 and the drain electrode 16 each include materials that form ohmic contacts with the 2DEG. Titanium (Ti), an Al (aluminum)/Ti stacked structure, or the like is used as the source electrode 15 and the drain electrode 16. Herein, “/” indicates that the lower layer is at the right side of “/”, and the upper layer is at the left side of “/”.

A first insulating film 20 is located on the barrier layer 14. As an example, silicon oxide such as SiO₂ or the like is used as the material of the first insulating film 20.

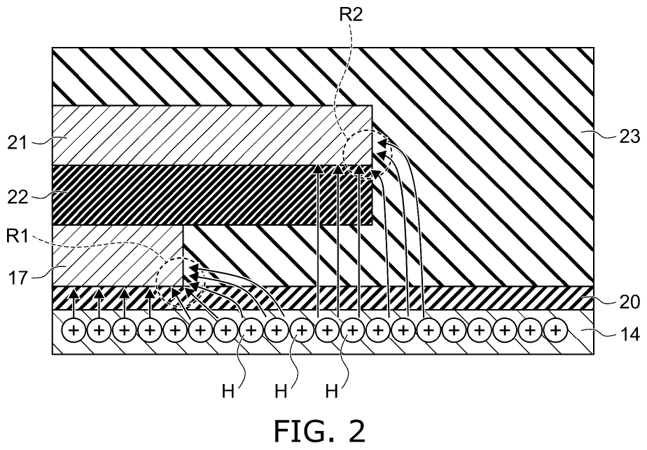

A gate electrode 17 (a first gate electrode) is located between the source electrode 15 and the drain electrode 16 on the first insulating film 20. The distance between the gate electrode 17 and the drain electrode 16 is set to be greater than the distance between the gate electrode 17 and the source electrode 15 to increase the breakdown voltage between the gate and drain. The gate electrode 17 and the barrier layer 14 have a Schottky junction. In other words, the gate electrode 17 includes a material that forms a Schottky junction with the barrier layer 14. The semiconductor device 1 shown in FIGS. 1A to 2 is a Schottky barrier HEMT. Nickel (Ni), a Au/Ni stacked structure, or the like is used as the gate electrode 17.

The Schottky barrier that is generated by the junction between the gate electrode 17 and the barrier layer 14 makes it possible to control the drain current. The mobility of carriers flowing through the two-dimensional electron gas is high, and so the semiconductor device 1 can perform extremely fast switching operations.

The semiconductor device 1 is not limited to a Schottky barrier HEMT; the semiconductor device 1 may be a MIS (Metal Insulator Semiconductor) HEMT in which a gate insulating film is interposed between the barrier layer 14 and the gate electrode 17. The junction gate structure also is applicable to a HEMT. The junction gate structure is configured by providing a p-type nitride semiconductor layer (e.g., a GaN layer) on the barrier layer 14, and by providing the gate electrode 17 on the p-type nitride semiconductor layer.

A gate field plate electrode 21 (a second gate electrode) is located above the gate electrode 17. The gate electrode 17 and the gate field plate electrode 21 are connected via a contact part 17a. The gate field plate electrode 21 juts from the connecting part between the gate field plate electrode 21 and the contact part 17a toward the source electrode 15 and toward the drain electrode 16.

A source field plate electrode 24 is located at the upper part of the source electrode 15. The source field plate electrode 24 juts toward the drain electrode 16 from the top of the source electrode 15.

A drain field plate electrode 25 is located at the upper part of the drain electrode 16. The drain field plate electrode 25 juts from the top of the drain electrode 16 toward the source electrode 15.

A second insulating film 22 is located between the gate electrode 17 and the gate field plate electrode 21. As an example as shown in FIG. 1B, the second insulating film 22 is located directly under the gate field plate electrode 21. More specifically, the side surface of the second insulating film 22 may be coplanar with the side surface of the gate field plate electrode 21. Silicon oxide such as SiO₂ or the like is used as the material of the second insulating film 22.

A third insulating film 23 is arranged around the gate electrode 17, the gate field plate electrode 21, and the second insulating film 22 on the first insulating film 20. The third insulating film 23 has a higher relative dielectric constant than the first and second insulating films 20 and 22. Silicon nitride such as SiN or the like is used as the material of the third insulating film 23.

An insulating layer 28 is located on the drain electrode 16, the source electrode 15, and the third insulating film 23. SiO₂ or the like is used as the material of the insulating layer 28.

A protective layer 27 is located on the insulating layer 28. The protective layer 27 also is referred to as a passivation layer. The protective layer 27 includes an insulator such as SiN, SiO₂, etc.

Effects of the semiconductor device 1 will now be described with reference to FIG. 2. In the semiconductor device 1 as shown in FIG. 2, when some of holes H generated in the barrier layer 14 under the first insulating film 20 flow toward a region R1 of the gate electrode 17, the higher relative dielectric constant of the third insulating film 23 relative to the first insulating film 20 causes lines of electric force to be drawn toward the third insulating film 23; and more holes H flow to the side surface of the gate electrode 17. Similarly, when some of the holes H generated in the barrier layer 14 flow toward a region R2 of the gate field plate electrode 21, the higher relative dielectric constant of the third insulating film 23 relative to the second insulating film 22 causes lines of electric force to be drawn toward the third insulating film 23; and more holes H flow toward the side surface of the gate field plate electrode 21.

Thus, because the semiconductor device 1 has a higher relative dielectric constant than the first and second insulating films 20 and 22 and includes the third insulating film 23 that is arranged around the gate electrode 17, the gate field plate electrode 21, and the second insulating film 22, lines of electric force can be drawn toward the third insulating film 23, which is a high dielectric constant material, thereby relaxing the electric field at the electrode edge to suppress current collapse, which in turn can improve the element life.

### 1.2 Manufacturing Method

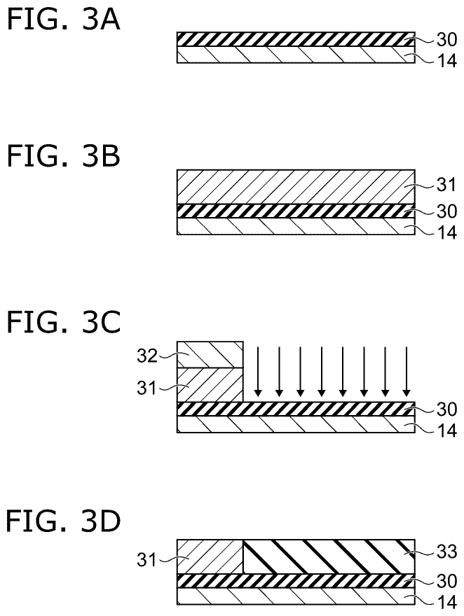

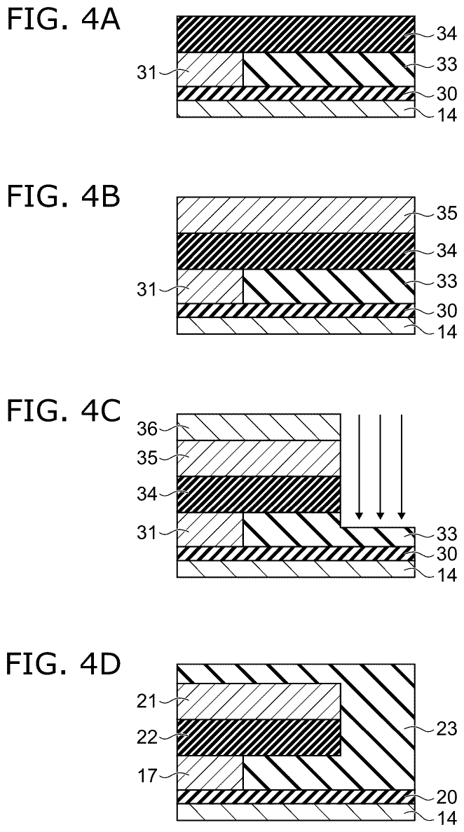

FIGS. 3A to 3D and FIGS. 4A to 4D are cross-sectional views showing a method for manufacturing the semiconductor device. The method for manufacturing the semiconductor device 1 will now be described with reference to FIGS. 3A to 4D. The substrate 10 is not illustrated in FIGS. 3A to 4D.

As shown in FIG. 3A, a silicon oxide film 30 (e.g., SiO₂) is formed by, for example, CVD (Chemical Vapor Deposition) on a wafer including the barrier layer 14 provided on a substrate. Then, as shown in FIG. 3B, a metal layer 31 (e.g., Al) is formed on the upper surface of the silicon oxide film 30 by sputtering.

Continuing as shown in FIG. 3C, a resist 32 is coated onto the metal layer 31; and a pattern is formed in the metal layer 31 by RIE (Reactive Ion Etching). Then, as shown in FIG. 3D, a silicon nitride film 33 (e.g., SiN) is formed by, for example, CVD.

Then, as shown in FIG. 4A, a silicon oxide film 34 (e.g., SiO₂) is formed on the upper surfaces of the metal layer 31 and the silicon nitride film 33 by, for example, CVD. Then, as shown in FIG. 4B, a metal layer 35 (e.g., Al) is formed on the upper surface of the silicon oxide film 34 by sputtering.

Continuing as shown in FIG. 4C, a resist 36 is coated onto the metal layer 35; and a pattern is formed in the metal layer 35 and the silicon oxide film 34 by RIE. Then, as shown in FIG. 4D, a silicon nitride film (e.g., SiN) is formed around the silicon oxide film 34 and the metal layer 35 by, for example, CVD. As a result, the metal layer 31 becomes the gate electrode 17; the silicon oxide film 30 becomes the first insulating film 20; the silicon oxide film 34 becomes the second insulating film 22; the metal layer 35 becomes the gate field plate electrode 21; and the third insulating film 23 is formed around the gate field plate electrode 21 and the second insulating film 22.

### 1.3 Modifications

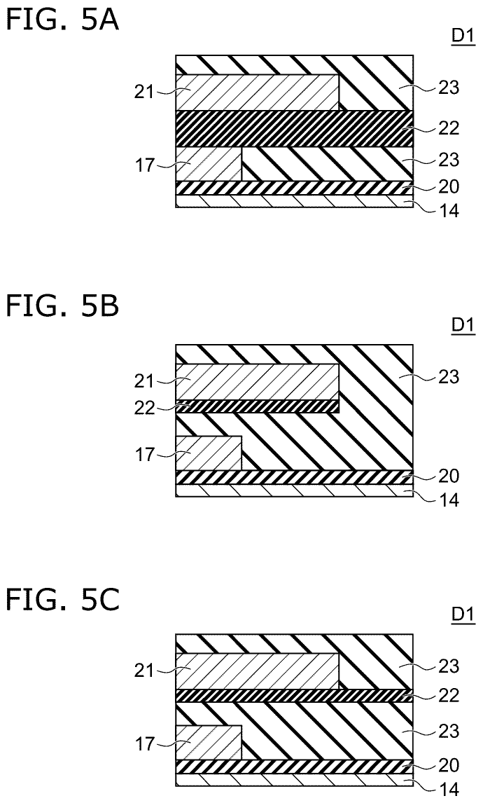

FIGS. 5A and 5B are cross-sectional views of modifications of the semiconductor device according to the first embodiment. Modifications of the semiconductor device 1 according to the first embodiment will now be described with reference to FIGS. 5A to 5C. As an example, in the semiconductor device 1 according to a modification as shown in FIG. 5A, the side surface of the second insulating film 22 may not be coplanar with the side surface of the gate field plate electrode 21. More specifically, the second insulating film 22 may be positioned in a region directly above the first insulating film 20 to be connected to both the source electrode 15 and the drain electrode 16.

As another example as shown in FIG. 5B, the second insulating film 22 may be located in only a portion of the region between the gate electrode 17 and the gate field plate electrode 21. More specifically, the second insulating film 22 may be positioned only at the gate field plate electrode 21 side in the region between the gate electrode 17 and the gate field plate electrode 21.

As another example as shown in FIG. 5C, the side surface of the second insulating film 22 may not be coplanar with the side surface of the gate field plate electrode 21; and the second insulating film 22 may be located only in a portion of the region between the gate electrode 17 and the gate field plate electrode 21. More specifically, the second insulating film 22 may be positioned in a region directly above the first insulating film 20 to be connected to both the source electrode 15 and the drain electrode 16; and the second insulating film 22 may be positioned only at the gate field plate electrode 21 side in the region between the gate electrode 17 and the gate field plate electrode 21.

Similarly to the first embodiment above, in the semiconductor device 1 according to such modifications, the lines of electric force can be drawn toward the third insulating film 23, which is a high dielectric constant material, thereby relaxing the electric field at the electrode edge to suppress current collapse, which in turn can improve the element life.

### 2. Second Embodiment

### 2.1 Semiconductor Device 2

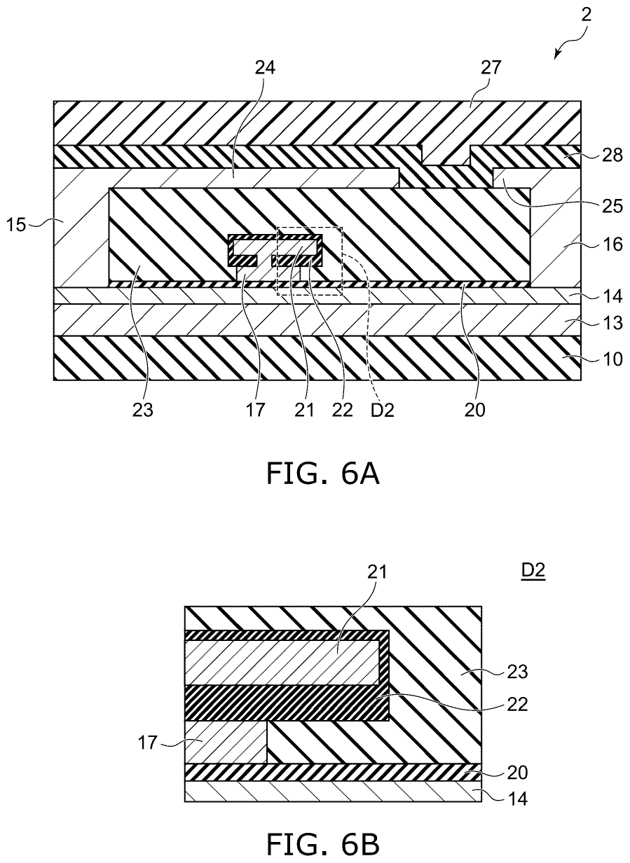

FIG. 6A is a cross-sectional view of a semiconductor device according to a second embodiment. FIG. 6B is an enlarged cross-sectional view of portion D2 of FIG. 6A. The semiconductor device 2 according to the second embodiment will now be described with reference to FIGS. 6A and 6B. The shape of the second insulating film 22 of the semiconductor device 2 differs from that of the first embodiment. The following description focuses on the difference.

In the semiconductor device 2 as shown in FIGS. 6A and 6B, the second insulating film 22 is arranged between the gate electrode 17 and the gate field plate electrode 21 and around the gate field plate electrode 21. As shown in FIG. 6B, the second insulating film 22 is arranged so that the outer edge of the second insulating film 22 is along the outer edge of the gate field plate electrode 21. Such a configuration can realize the effects of the first embodiment above. The second insulating film 22 includes SiO₂ and has a higher band offset than the third insulating film 23, which includes SiN, and so electrons injected into the gate field plate electrode 21 can be inhibited more, and an on-resistance increase can be further suppressed.

### 2.2 Modifications

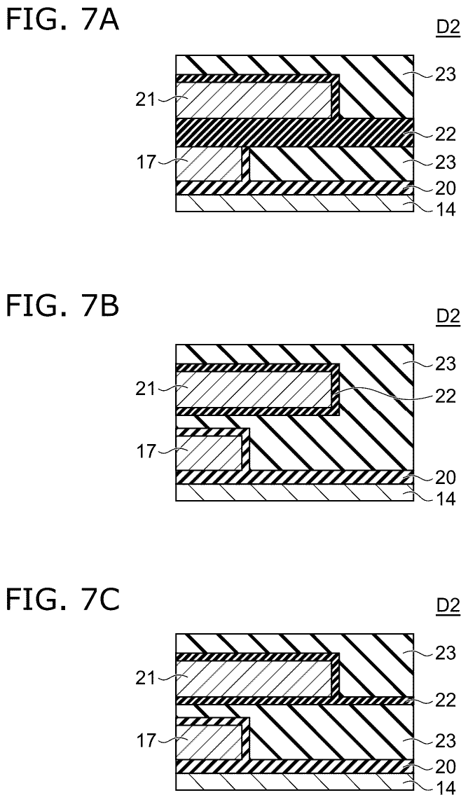

FIGS. 7A to 7C are cross-sectional views of modifications of the semiconductor device according to the second embodiment. Modifications of the semiconductor device 2 according to the second embodiment will now be described with reference to FIGS. 7A to 7C. As an example, in the semiconductor device 2 according to a modification as shown in FIG. 7A, the outer edge of the second insulating film 22 may not be along the outer edge of the gate field plate electrode 21. More specifically, the second insulating film 22 may be positioned in a region directly above the first insulating film 20 to be connected to both the source electrode 15 and the drain electrode 16.

As another example as shown in FIG. 7B, the first insulating film 20 may be arranged around the gate electrode 17; and the second insulating film 22 may be arranged around the gate field plate electrode 21. More specifically, the second insulating film 22 may be arranged so that the outer edge of the second insulating film 22 is along the outer edge of the gate field plate electrode 21; and spacing may be provided between the first insulating film 20 and the second insulating film 22.

As another example as shown in FIG. 7C, the first insulating film 20 may be arranged around the gate electrode 17; the second insulating film 22 may be arranged around the gate field plate electrode 21; and the outer edge of the second insulating film 22 may not be along the outer edge of the gate field plate electrode 21. More specifically, spacing may be provided between the first insulating film 20 and the second insulating film 22; and the second insulating film 22 may be positioned in a region directly above the first insulating film 20 to be connected to both the source electrode 15 and the drain electrode 16.

Similarly to the first embodiment above, in the semiconductor device 2 according to such modifications, the lines of electric force can be drawn toward the third insulating film 23, which is a high dielectric constant material, thereby relaxing the electric field at the electrode edge to suppress current collapse, which in turn can improve the element life.

### 3. Other Embodiments

While the semiconductor device 1 according to the embodiment is described above, applications of the technical ideas of the disclosure are not limited to the embodiments above. For example, according to the embodiments above, the first insulating film 20 and the second insulating film 22 include SiO₂, and the third insulating film 23 includes SiN; however, the technical ideas of the disclosure may be realized using other substances.

According to the embodiments, the semiconductor device includes a nitride semiconductor. However, the semiconductor device is not limited thereto; and a compound semiconductor other than a nitride semiconductor also is applicable.

In the specification, “nitride semiconductor” includes all compositions of semiconductors for which the composition ratios x and y of the chemical formula InₓAl_{y}Ga_{(1-x-y)}N (0≤x≤1, 0≤y≤1, and 0≤x+y≤1) are changed within the ranges respectively. “Nitride semiconductor” further includes Group V elements other than N (nitrogen) in the chemical formula above, various elements added to control various properties such as the conductivity type and the like, and various elements included unintentionally.

The disclosure can include the following features.

### Supplementary Note 1

A semiconductor device, including:
a compound semiconductor layer located on a substrate;
a first insulating film located on the compound semiconductor layer;
a first gate electrode located on the first insulating film;
a second gate electrode located above the first gate electrode;
a second insulating film located between the first gate electrode and the second gate electrode; and
a third insulating film arranged around the first gate electrode, the second gate electrode, and the second insulating film,
the third insulating film having a higher relative dielectric constant than the first and second insulating films.

### Supplementary Note 2

The semiconductor device according to Supplementary note 1, in which
a side surface of the second insulating film is coplanar with a side surface of the second gate electrode.

### Supplementary Note 3

A semiconductor device, including:
a compound semiconductor layer located on a substrate;
a first insulating film located on the compound semiconductor layer;
a first gate electrode located on the first insulating film;
a second gate electrode located above the first gate electrode;
a second insulating film arranged between the first gate electrode and the second gate electrode and around the second gate electrode; and
a third insulating film arranged around the first gate electrode and the second insulating film, the third insulating film having a higher relative dielectric constant than the first and second insulating films.

### Supplementary Note 4

The semiconductor device according to Supplementary note 3, in which
the second insulating film is arranged so that an outer edge of the second insulating film is along an outer edge of the second gate electrode.

### Supplementary Note 5

The semiconductor device according to any one of Supplementary notes 1 to 4, in which
the first insulating film and the second insulating film include SiO₂, and
the third insulating film includes SiN.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Moreover, above-mentioned embodiments can be combined mutually and can be carried out.

What is claimed is:

1. A semiconductor device, comprising:
a compound semiconductor layer located on a substrate;
a first insulating film located on the compound semiconductor layer;
a first gate electrode located on the first insulating film;
a second gate electrode located above the first gate electrode;
a second insulating film located between the first gate electrode and the second gate electrode; and
a third insulating film arranged around the first gate electrode, the second gate electrode, and the second insulating film,
the third insulating film having a higher relative dielectric constant than the first and second insulating films.

2. The semiconductor device according to claim 1, wherein
a side surface of the second insulating film is coplanar with a side surface of the second gate electrode.

3. The semiconductor device according to claim 1, wherein
the first insulating film and the second insulating film include SiO₂, and
the third insulating film includes SiN.

4. A semiconductor device, comprising:
a compound semiconductor layer located on a substrate;
a first insulating film located on the compound semiconductor layer;
a first gate electrode located on the first insulating film;
a second gate electrode located above the first gate electrode;
a second insulating film arranged between the first gate electrode and the second gate electrode and around the second gate electrode; and
a third insulating film arranged around the first gate electrode and the second insulating film, the third insulating film having a higher relative dielectric constant than the first and second insulating films.

5. The semiconductor device according to claim 4, wherein
the second insulating film is arranged so that an outer edge of the second insulating film is along an outer edge of the second gate electrode.

6. The semiconductor device according to claim 4, wherein
the first insulating film and the second insulating film include SiO₂, and
the third insulating film includes SiN.
